(19) United States
(12) Patent Application Publication
(10) Pub. No.: US 2009/0166077 A1
(43) Pub. Date: Jul. 2, 2009

(54) WIRING BOARD AND METHOD OF MANUFACTURING THE SAME

(75) Inventor: Eiichi Hirakawa, Nagano-shi (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD., NAGANO-SHI (JP)

(21) Appl. No.: 12/335,907

(22) Filed: Dec. 16, 2008

(30) Foreign Application Priority Data
Dec. 18, 2007 (JP) 2007-325747

(51) Int. Cl. H05K 1/00; H05K 1/11; C25D 5/02; H05K 3/00

(52) U.S. Cl. 174/262; 174/250; 205/125

(57) ABSTRACT

A wiring board is provided. The wiring board includes: a core substrate; wiring layers formed on the core substrate; and a reinforcement conductor which penetrates through the core substrate and which is formed by flat-plate-shaped conductor portions that intersect each other in a plan view. The reinforcement conductor is formed by intersecting vertical crosspieces and horizontal crosspieces and assumes a lattice form in the plan view.

This application claims priority from Japanese Patent Application No. 2007-325747, filed on Dec. 18, 2007, the entire contents of which are incorporated by reference herein.

### BACKGROUND

1. Technical Field

The present disclosure relates to a wiring board and its manufacturing method. More specifically, the present disclosure relates to a wiring board having a structure for suppressing warpage of the board as well as to its manufacturing method.

2. Related Art

Among wiring board products to be mounted with a semiconductor element or the like are ones that are formed by layering wiring layers on both surfaces of a core substrate which is a resin substrate such as a glass epoxy substrate and ones that are formed by layering wiring layers without using a core substrate.

In these wiring boards, an electric connection between wiring layers is made through via holes. Where a core substrate is used, electric continuity between wiring layers formed on both surfaces of the core substrate is established by forming through-holes through the core substrate and plating the inside surfaces of the through-holes.

Incidentally, wiring boards have become thinner gradually because semiconductor devices used in electronic equipment have been required to be reduced in size and thickness. This tendency has raised a problem that wiring boards are prone to warp. FIG. 8A illustrates a wiring board in which vias 6 are formed between wiring layers 5a and 5b. FIG. 8B shows how the wiring board is warped. Such warpage of the wiring board results in problems that a semiconductor element cannot be mounted on the wiring board correctly and that a semiconductor device cannot be mounted on the wiring board board in a reliable manner.

In particular, wiring boards not having a core substrate are more prone to warp than wiring boards having a core substrate because the former are low in shape retention, though the former can be made thin. Even wiring boards having a core substrate suffer a problem that they are prone to warp when their total thickness is reduced (see e.g., JP-A-2001-345526).

One method for preventing the above kind of warpage of a wiring board is to use, as a core substrate material, a material that is higher in rigidity such as a metal material. However, a wiring board using a new material causes an increase in cost. If the shape retention of a wiring board can be improved without using a reinforcement member such as a core substrate or by utilizing a conventional wiring board manufacturing process, it is very advantageous in terms of the manufacturing process and the manufacturing cost. And such a technique is very effective if it is also applicable to wiring boards not having a core substrate.

### SUMMARY OF THE INVENTION

Exemplary embodiments of the present invention address the above disadvantages and other disadvantages not described above. However, the present invention is not required to overcome the disadvantages described above, and thus, an exemplary embodiment of the present invention may not overcome any of the problems described above.

Accordingly, it is an aspect of the present invention to provide a wiring board which can suppress warpage of a wiring board by increasing its shape retention irrespective of whether it has a core substrate or not and which is thereby made highly reliable, as well as a manufacturing method of such a wiring board.

According to one or more aspects of the present invention, there is provided a wiring board including: a core substrate; wiring layers formed on the core substrate; and a reinforcement conductor which penetrates through the core substrate and which is formed by flat-plate-shaped conductor portions that intersect each other in a plan view.

According to one or more aspects of the present invention, the reinforcement conductor is formed by intersecting vertical crosspieces and horizontal crosspieces and assumes a lattice form in the plan view.

According to one or more aspects of the present invention, the wiring board further includes: a conduction through-hole formed through the core substrate to electrically connect the wiring layers formed on both surfaces of the core substrate.

According to one or more aspects of the present invention, there is provided a wiring board not having a core substrate. The wiring board includes: insulating layers; wiring patterns, wherein the insulating layers and the wiring layers are alternately layered; and a reinforcement conductor which penetrates through at least one of the insulating layers and which is formed by flat-plate-shaped conductor portions that intersect each other in a plan view.

According to one or more aspects of the present invention, the reinforcement conductor comprises a plurality of reinforcement conductor portions which are provided in a plurality of the insulating layers.

According to one or more aspects of the present invention, there is provided a method of manufacturing a wiring board. The method includes: forming penetration grooves through a core substrate made of resin such that the penetration grooves intersect each other in a plan view; performing plating on the core substrate formed with the penetration grooves; forming a reinforcement conductor by charging the penetration grooves with a metal; and forming wiring layers on the core substrate.

According to one or more aspects of the present invention, there is provided a method of manufacturing a wiring board not having a core substrate, the method includes: forming a seed layer on a base plate; alternately-forming wiring layers and insulating layers on the seed layer by built-up method; forming penetration grooves in at least one of the insulating layers, by laser working, such that the grooves intersect each other in a plan view; forming a reinforcement conductor by charging the penetration grooves with a metal through plating; and dissolving and removing the base plate by etching using the seed layer as an etching stopper layer.

According to the present invention, the reinforcement conductor is provided in the core substrate or at least one of the multiple wiring layers. This enables to prevent effectively the wiring board from warping, and thus the wiring board can be made highly reliable. Also, the manufacturing method of a wiring board according to the present invention provides advantages in that the wiring board having the reinforcement conductor can be manufactured without altering a conventional manufacturing method of a wiring board to a large extent.

Other aspects and advantages of the present invention will be apparent from the following description, the drawings, and the claims.

### BRIEF DESCRIPTION OF THE DRAWINGS

FIG. 1A is a sectional view showing the configuration of a wiring board according to an exemplary embodiment of the present invention;

FIG. 1B is a side view of a reinforcement conductor according to an exemplary embodiment of the present invention;

FIG. 2 is a perspective views of a reinforcement conductor;

FIGS. 3A and 3B are perspective views of other examples of reinforcement conductors;

FIGS. 4A to 4H are process views describing a manufacturing method of a wiring board according to an exemplary embodiment of the present invention;

FIGS. 5A and 5B are plan views showing examples of penetration grooves;

FIGS. 6A to 6D are process views describing another manufacturing method of a wiring board according to an exemplary embodiment of the present invention;

FIGS. 7A to 7D are process views describing said another manufacturing method of the wiring board according to the exemplary embodiment of the present invention; and

FIGS. 8A and 8B are views showing a wiring board having the related-art vias.

### DETAILED DESCRIPTION OF EXEMPLARY EMBODIMENTS OF THE PRESENT INVENTION

Exemplary embodiments of the present invention will be described with reference to the drawings hereinafter.

### (Configuration of Wiring Board)

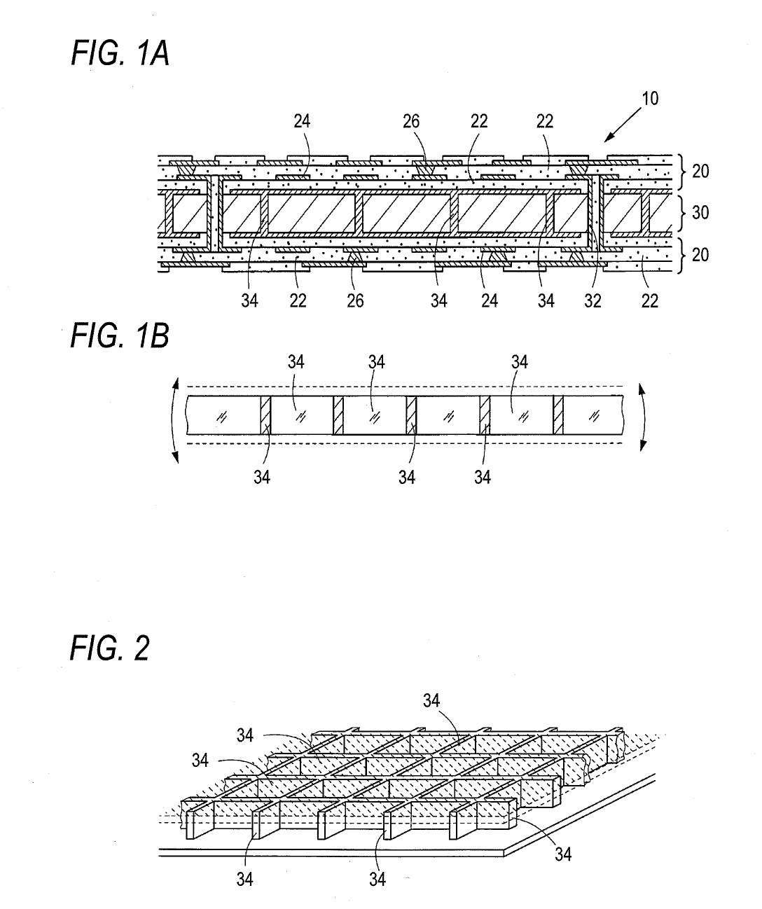

FIG. 1A is a sectional view showing an example configuration of a wiring board according to an exemplary embodiment of the present invention. The wiring board 10 according to this embodiment is formed by providing build-up layers 20 on both surfaces of a core substrate 30 which is mainly made of glass epoxy. The build-up layers 20 are formed by layering wiring patterns 24 with insulating layers 22 interposed therebetween and electrically connecting the wiring patterns 24 in different layers to each other via a via 26.

Each of conduction through-holes 32 serves to electrically connect the wiring patterns 24 provided in build-up layers 20 formed on both surfaces of the core substrate 30 and is formed through the core substrate 30. Each conduction through-hole 32 is formed by plating, with a conductive layer, the inside wall surface of a through-hole that penetrates through the core substrate 30 in its thickness direction.

The wiring board 10 according to the embodiment is characterized in that the core substrate 30 is provided with a reinforcement conductor 34 for increasing the shape retention of the wiring board 10. The reinforcement conductor 34 is configured in such a manner that flat-plate-shaped conductor portions are disposed inside the core substrate 30 in parallel with its thickness direction so as to assume a lattice form in a plan view.

FIG. 1B is a side view of the reinforcement conductor 34 formed inside the core substrate 30. The height of the reinforcement conductor 34 is set so that it traverses the core substrate 30 in its thickness direction.

FIG. 2 is a perspective view showing the structure of the reinforcement conductor 34 provided inside the core substrate 30. The reinforcement conductor 34 is configured in such a manner that vertical crosspieces and horizontal crosspieces intersect each other at right angles. Although in the embodiment the interval between the vertical crosspieces is the same as that of the horizontal crosspieces and hence each lattice section of the reinforcement conductors 24 is a square, this structure of the reinforcement conductor 24 is not the only possible structure. For example, each lattice section may have other shapes such as a rectangle or a hexagon.

In the wiring board 10 according to the embodiment, the flat-plate-shaped conductor portions are incorporated in the core substrate 30 so as to intersect each other and assume a lattice form in a plan view. By virtue of this configuration, the wiring board 10 is prevented effectively from bending or warping. Since strong force is needed to bend, in its thickness direction, the reinforcement conductor 34 which is formed by the flat-plate-shaped conductors, the wiring board 10 is available as a warpage-suppressed wiring board even if the core substrate 30 is made thinner.

The configuration of the wiring board 10 is the same as conventional wiring boards having a core substrate except that the core substrate 30 is provided with the reinforcement conductor 34. The reinforcement conductor 34 which is provided in the core substrate 30 can be disposed properly by taking into consideration the arrangement of the conduction through-holes 32 which are formed in the core substrate 30.

Of course, it is possible to use the reinforcement conductor 34 as a conductor that is electrically connected to common potential layers such as ground layers or power layers of the build-up layers 20 which are formed on both surfaces of the core substrate 30. Since the reinforcement conductor 34 can secure a relatively wide area, the reinforcement conductor 34 provides an advantage that it can reduce the electrical resistance.

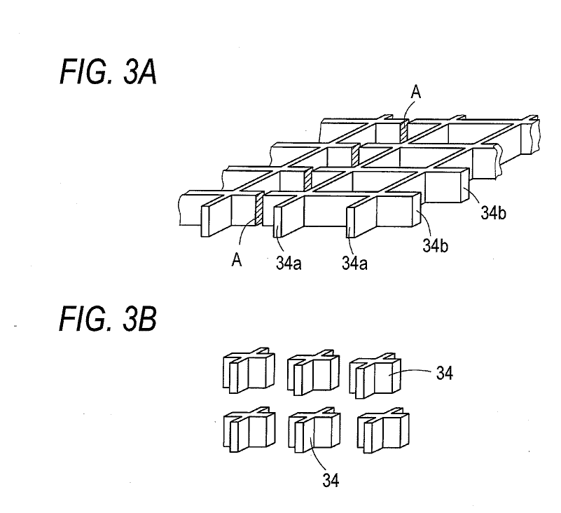

The reinforcement conductor 34 need not always be a fully integral member as shown in FIG. 2. FIG. 3A shows an example in which the reinforcement conductor 34 is cut (cutting surfaces are denoted by character A) into several blocks which are disposed so as to be separated from each other in a plan view taken parallel with the wiring board 10 and each of which is connected to ground layers, power layers, or the like. FIG. 3B shows another example in which flat-plate-shaped conductors intersect each other so as to assume a cross in a plan view to form each single reinforcement conductor 34.

The example of FIG. 3B in which each reinforcement conductor 34 is formed by flat-plate-shaped conductors so as to have projections arranged radially can make the shape retention of the wiring board 10 higher than in a case that cylindrical conductors are merely formed, and hence is effective in preventing warpage of the wiring board 10.

The method of disposing separate reinforcement conductors 34 as in the example of FIG. 3B is effective in securing spaces for disposing the reinforcement conductors 34 in the case where the density of the conduction through-holes 32 in the core substrate 30 is high and a single reinforcement conductor 34 cannot be disposed over the entire width of the core substrate 30.

### (Manufacturing Method 1 of Wiring Board)

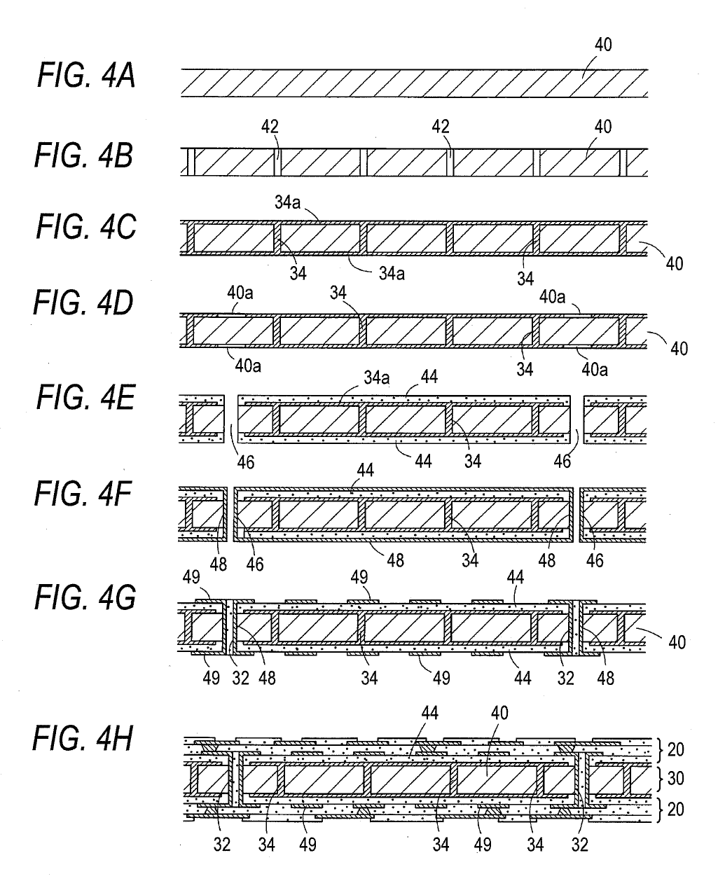

FIGS. 4A to 4H show an example of manufacturing method of a wiring board having a core substrate.

FIG. 4A shows a resin substrate 40 made of glass epoxy or the like, from which a core substrate 30 is to be formed. First, the resin substrate 40 is subjected to laser working; whereby penetration grooves 42 are formed at positions where a reinforcement conductor 34 is to be formed (penetration grooves forming step). FIG. 4B shows a state that the penetration grooves 42 are formed through the resin substrate 40. In this embodiment, a reinforcement conductor 34 will be formed so as to assume a lattice form in a plan view. Therefore, the penetration grooves 42 are formed by laser working (digging) in an arrangement that conforms to the intended plan-view shape of the reinforcement conductor 34.

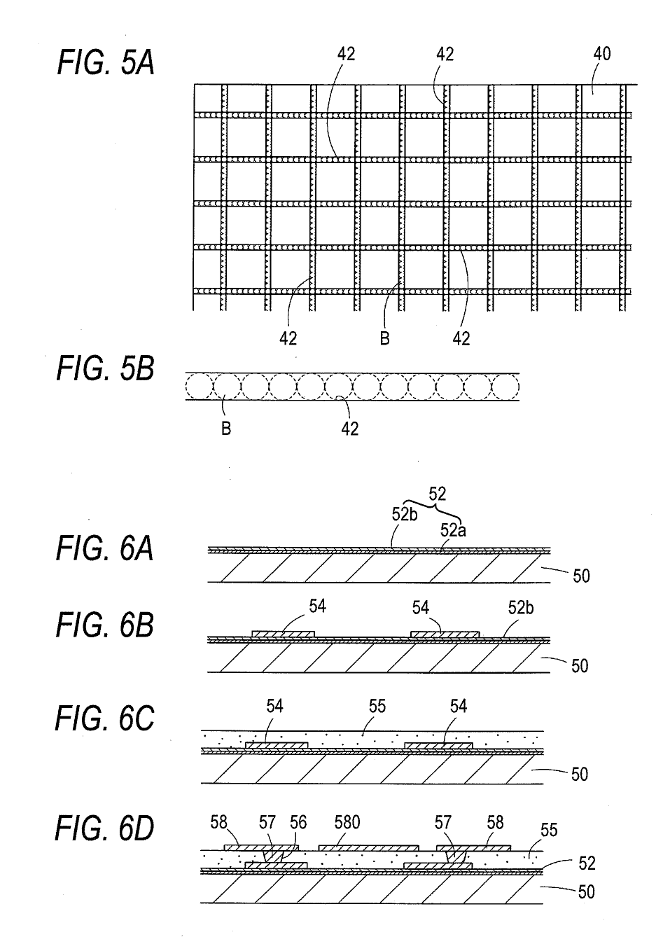

FIG. 5A is a plan view of the resin substrate 40 that is formed with the penetration grooves 42. Since the reinforcement conductor 34 is to be formed by charging a conductive material into the penetration grooves 42, in forming the penetration grooves 42 by laser working, the laser beam diameter is set by taking the thickness of the reinforcement conductor 34 into consideration. Since a reinforcement conductor 34 needs to be formed as an integral structure of flat-plate-shaped conductor portions, the penetration grooves 42 are formed as continuous grooves that communicate with each other.

FIG. 5B is an enlarged view of the penetration groove 42. A continuous penetration groove 42 can be formed by sweeping laser beam (illumination positions are indicated by character B) continuously. However, if the penetration grooves 42 intersected each other in lattice form and fully penetrated through the resin substrate 40, individual sections of the resulting resin substrate 40 would fall off. Therefore, partial links for linking adjoining sections are formed. Alternatively, a backing tape for supporting the resin substrate 40 may be affixed to its top surface or bottom surface.

The method for forming the penetration grooves 42 through the resin substrate 40 is not limited to laser working. The penetration grooves 42 may be formed by drilling or some other working method. Even if drilling does not produce penetration grooves 42 that fully communicate with each other, the resulting penetration grooves 42 that communicate with each other partially can provide a sufficient reinforcement effect.

FIG. 4C shows a reinforcement conductor 34 formed by charging a conductive material into the penetration grooves 42 by plating. First, electroless copper plating is performed on the resin substrate 40 that is formed with the penetration grooves 42, whereby plating seed layers are formed on the inside surfaces of the penetration grooves 42 and the surfaces of the resin substrate 40. Then, electrolytic copper plating is performed with the plating seed layers as plating electricity supply layers, whereby copper is charged into the penetration grooves 42 by plating. At the same time, copper layers 34a are deposited on the surfaces of the resin substrate 40. A reinforcement conductor 34 is formed in lattice form (see FIG. 2) by the charging of copper into the penetration grooves 42. Although in the embodiment the reinforcement conductor 34 is formed by electrolytic copper plating, plating other than copper plating, such as nickel plating, may be employed.

FIGS. 4D to 4F are steps for forming conduction through-holes through a core substrate 30. FIG. 4D shows a state that portions 40a of the resin substrate 40, where conduction through-holes 32 are to be formed, have been exposed by etching away the corresponding portions of the copper layers 34a deposited on the surfaces of the resin substrate 40. FIG. 4E shows a state that through-holes 46 have been formed at the positions, where the conduction through-holes 32 are to be formed, after coating the surfaces of the resin substrate 40 with insulating layers 44. Electroless copper plating and electrolytic copper plating are performed in this state, whereby copper layers 48 are deposited on the inside surfaces of the through-holes 46 and the surfaces of the insulating layers 44 (see FIG. 4F).

Then, the copper layers 48 covering the surfaces of the insulating layers 44 are pattern-etched, whereby wiring patterns 49 are formed on the surfaces of the insulating layers 44 and conduction through-holes 32 are formed. Each conduction through-hole 32, more specifically, the copper layer 48 that is deposited on the inside surface of each through-hole 46, electrically connects associated wiring patterns 49 formed on both surfaces of the core substrate 30 (see FIG. 4G).

FIG. 4H shows a state that a wiring board has been formed by layering wiring layers on both surfaces of the core substrate 30 through which the conduction through-holes 32 are formed. The wiring layers can be formed by a build-up method.

The wiring board 10 as shown in FIGS. 1A and 1B is thus completed in which the core substrate 30 is provided with the reinforcement conductor 34.

The manufacturing method of a wiring board according to the exemplary embodiment can produce the wiring board 10 having the reinforcement conductor 34 by utilizing, as it is, the conventional wiring board manufacturing method in which conduction through-holes 32 are formed by forming through-holes through a core substrate. Therefore, there are advantages in that the wiring board 10 can be manufactured without the need for altering the conventional manufacturing method to a large extent and it can be manufactured by utilizing a conventional manufacturing apparatus.

### (Manufacturing Method 2 of Wiring Board)

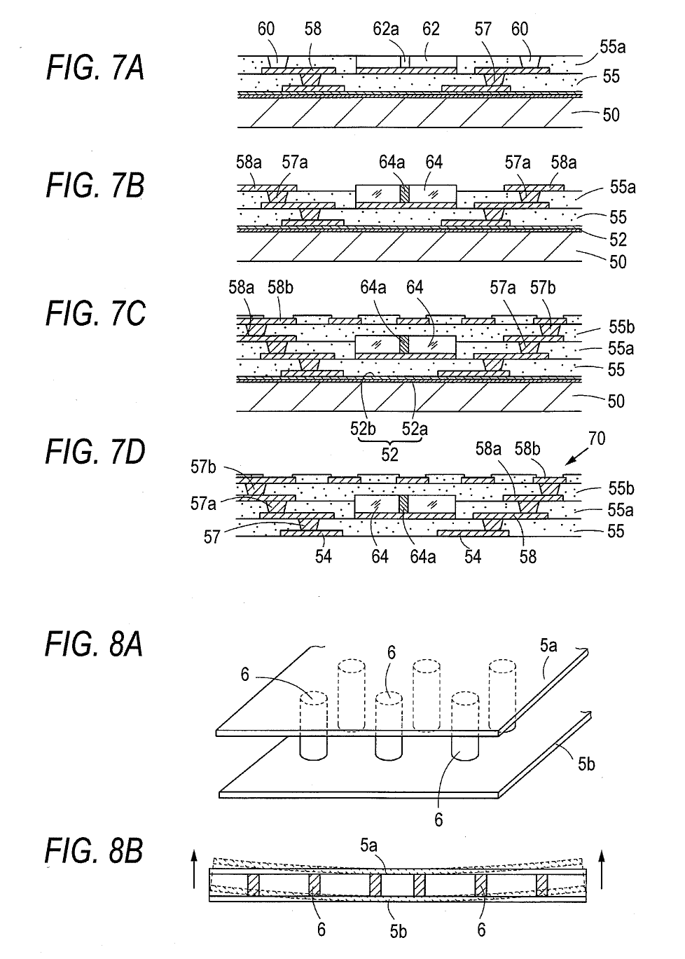

FIGS. 6A to 7D show a manufacturing method for incorporating a reinforcement conductor into a wiring board not having a core substrate.

First, FIG. 6A shows a state that a chromium (Cr) layer 52a is formed as part of a seed layer on one surface of a copper plate 50 as a base substrate and a copper layer 52b is formed on the surface of the chromium layer 52a. The copper plate 50 will be used as a support substrate for supporting layered wiring layers and will be dissolved and removed by chemical etching in a later step.

The chromium layer 52a of the seed layer 52 will be used as a stopper layer for stopping etching when the copper plate 50 will have been dissolved and removed by the etching. Such a layer may be made of a metal other than chromium as long as it is not etched with an etching liquid for etching the copper plate 50.

The copper layer 52b will be used as a plating electricity supply layer in forming connection pads or wiring patterns by electrolytic plating. Therefore, the copper layer 52b is formed at a thickness of about 0.1 μm.

FIG. 6B shows a state that connection pads 54, which are to be exposed in the outside surface of a wiring board, are formed on the surface of the copper layer 52b which is formed on the surface of the copper plate 50. The connection pads 54 are formed by: coating the surface of the copper layer 52b with a resist; forming a resist pattern such that portions of the copper layer 52b, where the connection pads 54 are to be formed, is exposed by exposing the resist to light and developing it; and depositing copper on the exposed portions of the copper layer 52b by electrolytic copper plating using the copper layer 52b as a plating electricity supply layer.

Then, the entire surface of the copper plate 50 including the connection pads 54 are covered with an insulating layer 55 by laminating, on the copper plate 50, an insulating film which is made of an electrically-insulation material such as polyimide (see FIG. 6C).

FIG. 6D shows a state that via holes 56 have been formed through the insulating layer 55 by laser working, vias 57 have been formed by via fill plating, and wiring patterns 58 have been formed on the surface of the insulating layer 55. The vias 57 and the wiring patterns 58 are formed by a known method such as a semi-additive method.

FIGS. 7A to 7D show steps characteristic of the embodiment that serve to incorporate a reinforcement conductor into one of laminated insulating layers. FIG. 7A shows a state that via holes 60 and grooves 62 for formation of a reinforcement conductor have been formed after forming an insulating layer of the next layer by laminating an insulating film on the surface of the insulating layer 55. For example, as in the above-described embodiment, the grooves 62 are formed so as to assume a cruciform shape in a plan view. By leaving a conductor pattern 580 so that it conforms to the intended pattern of the grooves 62 in forming the wiring patterns 58 in the preceding step, influence on the underlying insulating layer 55 can be avoided in forming the grooves 62 by laser working. In FIG. 7A, a groove 62a indicates that the grooves 62 are formed so as to assume a cruciform shape.

FIG. 7B shows a state that vias 57a have been formed by charging copper into the via holes 60 by via fill plating, a reinforcement conductor 64 has been formed by charging copper into the grooves 62, and wiring patterns 58a have been formed. As in the previous step, the vias 57a, the reinforcement conductor 64, and the wiring patterns 58a can be formed by a semi-additive method, for example.

The reinforcement conductor 64 is formed as an integral structure of copper flat-plate-shaped conductor portions that are formed by plating and intersect each other so as to assume a cruciform shape, and penetrates through the insulating layer 55a in the thickness direction. Like the reinforcement conductor(s) 34 according to the above embodiments, the reinforcement conductor 64 is configured to suppress warpage of the wiring board.

FIG. 7C shows a state that an insulating layer 55b, vias 57b, and wiring patterns 58b of the next layer are formed additionally. This wiring layer is formed by the same method as the known build-up method. Further wiring layers may be laminated by applying the build-up method repeatedly. Multiple wiring layers having a desired number of layers can thus be formed.

FIG. 7D shows a state that a multilayer wiring board 70 has been completed by removing the copper plate 50 as a base substrate from the laminated body of wiring layers by etching. A method for exposing the connection pads 54 in the outside surface of the board by etching away the copper plate 50 is as follows.

First, the copper plate 50 is etched away by using a copper etchant. This etching is finished at the time when the chromium layer 52a of the seed layer 52 is exposed. Then, the chromium layer 52a is etched away by using an etchant capable of etching the chromium layer 52a selectively. Etching of the copper layer 52b is started upon its exposure. Since the copper layer 52b is much thinner than the connection pads 54, only the copper layer 52b can be removed by selective-etching which uses a copper etchant.

The wiring board 70 is thus obtained in which the reinforcement conductor 64 is formed in the inside one of the laminated wiring layers. In FIG. 7D, a reinforcement conductor portion 64a indicates that the reinforcement conductor 64 is formed so as to assume a cruciform shape in a plan view.

Having the reinforcement conductor 64 in the inside layer, the wiring board 70 according to the exemplary embodiment has a function of suppressing its warpage. Although as shown in FIG. 7D the one reinforcement conductor 64 is formed in the inside layer 55a of the wiring board 70, reinforcement conductors 64 can be provided at proper positions of the insulating layer 55a. Furthermore, the reinforcement conductors 64 can be provided in any positions of the laminated wiring layers. It is also possible to provide the reinforcement conductors 64 at positions close to the outer periphery of the board where a warp is prone to occur. Thus, the reinforcement conductors 64 can be provided so as to suppress warpage of the wiring board 70 effectively.

Although the above exemplary embodiments are described in connection with the case that the reinforcement conductor(s) is formed in the coreless multilayer wiring board, the concept of the exemplary embodiments is applicable to a wiring board in which wiring layers are formed on a core substrate as in the first embodiment. Namely, reinforcement conductors may be provided in wiring layers in the same manner as in this embodiment in forming wiring layers on both surfaces of the core substrate.

The manufacturing method of a wiring board according to the exemplary embodiments utilizes a conventional manufacturing method for manufacturing a coreless multilayer wiring board using a base substrate, and hence provides an advantage in that a warpage-suppressed wiring board can be produced by utilizing the conventional manufacturing method as it is. Furthermore, incorporating a reinforcement conductor(s) in a coreless wiring board which is prone to warp makes it possible to suppress warpage of the wiring board effectively and to thereby make the wiring board highly reliable.

While the present invention has been shown and described with reference to certain exemplary embodiments thereof, it will be understood by those skilled in the art that various changes in form and details may be made therein without departing from the spirit and scope of the invention as defined by the appended claims. It is aimed, therefore, to cover in the appended claim all such changes and modifications as fall within the true spirit and scope of the present invention.

What is claimed is:

1. A wiring board comprising:
a core substrate;
wiring layers formed on the core substrate; and
a reinforcement conductor which penetrates through the core substrate and which is formed by flat-plate-shaped conductor portions that intersect each other in a plan view.

2. The wiring board according to claim 1, wherein the reinforcement conductor is formed by intersecting vertical crosspieces and horizontal crosspieces and assumes a lattice form in the plan view.

3. The wiring board according to claim 1, further comprising:
a conduction through-hole formed through the core substrate to electrically connect the wiring layers formed on both surfaces of the core substrate.

4. A wiring board not having a core substrate, comprising:
insulating layers;
wiring patterns, wherein the insulating layers and wiring layers are alternately layered; and
a reinforcement conductor which penetrates through at least one of the insulating layers and which is formed by flat-plate-shaped conductor portions that intersect each other in a plan view.

5. The wiring board according to claim 4, wherein the reinforcement conductor comprises a plurality of reinforcement conductor portions which are provided in a plurality of the insulating layers.

6. A method of manufacturing a wiring board, the method comprising:
forming penetration grooves through a core substrate made of resin such that the penetration grooves intersect each other in a plan view;
performing plating on the core substrate formed with the penetration grooves;
forming a reinforcement conductor by charging the penetration grooves with a metal; and
forming wiring layers on the core substrate.

7. A method of manufacturing a wiring board not having a core substrate, the method comprising:
forming a seed layer on a base plate;
alternately-forming wiring layers and insulating layers on the seed layer, by built-up method;
forming penetration grooves in at least one of the insulating layers, by laser working, such that the grooves intersect each other in a plan view;
forming a reinforcement conductor by charging the penetration grooves with a metal through plating; and
dissolving and removing the base plate by etching using the seed layer as an etching stopper layer.
